(19) United States
(12) Patent Application Publication
(10) Pub. No.: US 2023/0332032 A1
(43) Pub. Date: Oct. 19, 2023

(54) OXIDE POWDER AND METHOD FOR PRODUCING SAME, AND RESIN COMPOSITION

(71) Applicant: DENKA COMPANY LIMITED, Tokyo (JP)

(72) Inventors: Takuto OKABE, Tokyo (JP); Motoharu FUKAZAWA, Tokyo (JP)

(73) Assignee: DENKA COMPANY LIMITED, Tokyo (JP)

(21) Appl. No.: 18/026,889

(22) PCT Filed: Sep. 22, 2021
(86) PCT No.: PCT/JP2021/034745

§ 371 Date: Mar. 17, 2023

(30) Foreign Application Priority Data
Sep. 25, 2020 (JP) 2020-160393

(51) Int. Cl. C09K 5/14; C01B 33/26; C08K 3/34; H05K 1/03

(52) U.S. Cl. CPC C09K 5/14; C01B 33/26; C08K 3/34; H05K 1/0373; C01P 2006/32; C01P 2002/52; C01P 2004/61; C01P 2004/62; C01P 2006/12; C01P 2002/72; C08K 2201/001; C08K 2003/343; C08K 2201/005

(57) ABSTRACT

Oxide powder, of which a resin composition is obtained by mixing with a resin exhibits a low thermal expansion coefficient, high thermal conductivity and a low dielectric tangent. The oxide powder containing Ca, Al and Si; wherein the oxide powder contains 40% by mass or more of a crystal phase of high-temperature type cristobalite having Ca, Al and Si, based on the mass of the whole oxide powder; and wherein contents of Ca, Al and Si in the oxide powder are 1 to 5% by mole of CaO, 1 to 5% by mole of Al₂O₃ and 90 to 98% by mole of SiO₂, respectively (the sum of contents of CaO, Al₂O₃ and SiO₂ is 100% by mole) when converting the contents of Ca, Al and Si to contents of CaO, Al₂O₃ and SiO₂.

### TECHNICAL FIELD

The present invention relates to oxide powder and a method for producing the same, and a resin composition.

### BACKGROUND ART

Recently, with an increase of data traffic in a communication field, utilization of high-frequency band is spread in electronic equipment, telecommunication equipment, etc., and with respect to a material used in a device for high-frequency band, required are low dielectric constant and low dielectric tangent. Further, miniaturization and high integration of related electronic materials and members also progress, and a further heat dissipation property is being demanded.

As a ceramic material for high-frequency band, silica (SiO₂) has a small dielectric constant (3.7) and a quality coefficient indicator Qf (a value obtained by multiplying the reciprocal of the dielectric tangent by the observed frequency) of around 120 thousand, and thus it is promising as a material for a filler having a low dielectric constant and a low dielectric tangent. In addition, to facilitate blending in a resin, the filler shape is preferred to be as close as a spherical shape. Spherical silica can be easily synthesized (e.g., PTL 1), and has already been used in many applications. Therefore, it is expected to be widely used even in high frequency band dielectric devices and the like.

However, the above spherical silica is generally amorphous, and its thermal conductivity is low of about 1 W/m·K, and thus there is a case that a resin composition filled with the spherical silica has insufficient heat dissipation.

To improve the thermal conductivity, it is considered that the spherical silica is crystallized from amorphous to quartz, cristobalite, and the like. PTL 2 and PTL3, for example, propose that the amorphous spherical silica is heat treated to crystallize to quartz particles and cristobalite. However, low-temperature type quartz and low-temperature type cristobalite have high thermal expansion coefficient, and thus it is difficult to reduce the thermal expansion coefficient of substrates and the like.

To reduce the thermal expansion coefficient, it is considered that these can be crystallized to high-temperature type quartz and high-temperature type cristobalite. PTL 4, for example, discloses crystallization to high-temperature type quartz and high-temperature type cristobalite. However, in PTL 4, these are coating layers of a sintered body and not appropriate for the filler for electronic materials because of using a halide as a raw material.

### CITATION LIST

### Patent Literature

PTL 1: Japanese Patent Laid-Open No. 58-138740
PTL 2: Japanese Patent No. 6207753
PTL 3: International Publication No. WO 2018/186308
PTL 4: Japanese Patent Laid-Open No. 2002-154818

### SUMMARY OF INVENTION

### Technical Problem

An objective of the present invention is to provide oxide powder, of which a resin composition obtained by mixing with a resin exhibits a low thermal expansion coefficient, high thermal conductivity and a low dielectric tangent, and a method for producing the same, and the resin composition.

### Solution to Problem

The present invention includes the following embodiments.

[1] Oxide powder containing Ca, Al and Si;
wherein the oxide powder contains 40% by mass or more of a crystal phase of high-temperature type cristobalite having Ca, Al and Si, based on the mass of the whole oxide powder; and
wherein contents of Ca, Al and Si in the oxide powder are 1 to 5% by mole of CaO, 1 to 5% by mole of Al₂O₃ and 90 to 98% by mole of SiO₂, respectively (the sum of contents of CaO, Al₂O₃ and SiO₂ is 100% by mole) when converting the contents of Ca, Al and Si to contents of CaO, Al₂O₃ and SiO₂.

[2] The oxide powder according to [1], wherein the oxide powder contains 60% by mass or more of the crystal phase, based on the mass of the whole oxide powder.

[3] The oxide powder according to [1] or [2], wherein the oxide powder contains 30% by mass or less of a crystal phase of low-temperature type cristobalite having Si or Si and at least either one of Ca and Al, based on the mass of the whole oxide powder.

[4] The oxide powder according to any one of [1] to [3], wherein an average particle diameter of the oxide powder is 0.1 to 20 μm.

[5] The oxide powder according to any one of [1] to [4], wherein a content of halogen in the oxide powder is 0.1% by mass or less, based on the mass of the whole oxide powder.

[6] The oxide powder according to any one of [1] to [5], wherein the sum of contents of Li, Na and K in the oxide powder is less than 500 ppm by mass, respectively, based on the mass of the whole oxide powder.

[7] A method for producing the oxide powder according to any one of [1] to [6], including:
a step of mixing a Ca compound having a specific surface area of 2 m²/g or more, an Al compound having a specific surface area of 2 m²/g or more and SiO₂ to obtain a mixture; and
a step of heating the mixture at 1,000 to 1,300° C.

[8] A resin composition containing the oxide powder according to any one of [1] to [6] and a resin.

[9] The resin composition according to [8], wherein a content of the oxide powder in the resin composition is 2 to 89% by mass.

[10] The resin composition according to [8] or [9], which is a resin composition for high frequency substrate.

### Advantageous Effects of Invention

According to the present invention, oxide powder, of which a resin composition obtained by mixing with a resin exhibits a low thermal expansion coefficient, high thermal conductivity and a low dielectric tangent, and a method for producing the same, and the resin composition, can be provided.

### BRIEF DESCRIPTION OF DRAWINGS

FIG. 1 is a FIGURE showing an X-ray diffraction pattern of oxide powder of Example 1.

### DESCRIPTION OF EMBODIMENTS

Hereinafter, embodiments of the present invention will be described. However, the present invention is not limited to the following embodiments.

[Oxide Powder]

Oxide powder according to the present embodiments contains Ca, Al and Si. Here, the oxide powder contains 40% by mass or more of a crystal phase of high-temperature type cristobalite having Ca, Al and Si, based on the mass of the whole oxide powder (i.e., the mass of the whole oxide powder is 100% by mass). In addition, contents of Ca, Al and Si in the oxide powder are 1 to 5% by mole of CaO, 1 to 5% by mole of Al₂O₃, and 90 to 98% by mole of SiO₂, respectively, when converting the contents of Ca, Al and Si to contents of CaO, Al₂O₃ and SiO₂ (hereinafter, also referred to as converted contents). Further, in the converted contents, the sum of the contents of CaO, Al₂O₃ and SiO₂ is 100% by mole.

In the oxide powder according to the present embodiments, the oxide powder contains 40% by mass or more of the crystal phase in the high-temperature type cristobalite having Ca, Al and Si, and each composition ratio of Ca, Al and Si is in a predetermined range, and therefore a resin composition containing the oxide powder can exhibit a low thermal expansion coefficient, high thermal conductivity and a low dielectric tangent. The crystal phase in the high-temperature type cristobalite according to the present embodiments has a structure stabilized even at room temperature because predetermined amounts of calcium and aluminum form solid solution in the high-temperature type cristobalite, and phase transition at 220 to 260° C., that is confirmed in the low-temperature type cristobalite, is not occurred. Since the oxide powder according to the present embodiments contains 40% by mass or more of the crystal phase, the thermal expansion coefficient of the resin composition can be reduced. Further, the crystal phase can exhibit the high thermal conductivity and the low dielectric tangent in the resin composition similar to ordinary low-temperature type cristobalite.

The converted content of Ca as CaO in the oxide powder is 1 to 5% by mole, preferably 1.5 to 4.5% by mole, more preferably 2 to 4% by mole, and even more preferably 3 to 4% by mole. When the converted content is less than 1% by mole, crystallization is difficult to progress, to cause a decrease in thermal conductivity and/or an increase in dielectric tangent in the resin composition. When the converted content is more than 5% by mole, a content of the crystal phase in the high-temperature type cristobalite is decreased, to cause an increase in thermal expansion coefficient, an increase in dielectric tangent and/or a decline in reliability to an electric material, in the resin composition.

The converted content of Al as Al₂O₃ in the oxide powder is 1 to 5% by mole, preferably 1.5 to 4.5% by mole, more preferably 2 to 4% by mole, and even more preferably 3 to 4% by mole. When the converted content is less than 1% by mole, crystallization is difficult to progress, to cause a decrease in thermal conductivity and/or an increase in dielectric tangent in the resin composition. When the converted content is more than 5% by mole, the content of the crystal phase in the high-temperature type cristobalite is decreased, to cause the increase in thermal expansion coefficient and/or the increase in dielectric tangent in the resin composition.

The converted content of Si as SiO₂ in the oxide powder is 90 to 98% by mole, preferably 91 to 97% by mole, more preferably 92 to 96% by mole, and even more preferably 92 to 94% by mole. When the converted content is more than 98% by mole, the crystallization is difficult to progress, to cause the decrease in thermal conductivity and/or the increase in dielectric tangent in the resin composition. When the converted content is less than 90% by mole, the content of the crystal phase in the high-temperature type cristobalite is decreased, to cause the increase in thermal expansion coefficient, the increase in dielectric tangent and/or the decline in reliability to the electric material in the resin composition.

In the converted contents, the sum of the contents of CaO, Al₂O₃ and SiO₂ is 100% by mole. Measurement of the converted content of Ca as CaO, the converted content of Al as Al₂O₃ and the converted content of Si as SiO₂ is performed by inductively coupled plasma emission spectrometric analysis. Specifically, the measurement can be performed by a method described later.

The oxide powder contains 40% by mass or more of the crystal phase in the high-temperature type cristobalite having Ca, Al and Si, based on the mass of the whole oxide powder (i.e., the mass of the whole oxide powder is 100% by mass). When a content ratio of the crystal phase in the high-temperature type cristobalite is less than 40% by mass, the increase in thermal expansion coefficient, the decrease in thermal conductivity and/or the increase in dielectric tangent are caused in the resin composition. The content ratio of the crystal phase in the high-temperature type cristobalite is preferably 45% by mass or more, more preferably 50% by mass or more, and even more preferably 55% by mass or more. An upper limit of a range of the content ratio of the crystal phase in the high-temperature type cristobalite is not limited, and can be, e.g., 90% by mass or less. Furthermore, a structure of the crystal phase in the high-temperature type cristobalite according to the present embodiments is a structure stabilized even at room temperature in which a trace amount of the calcium and the aluminum makes solid solution in the high-temperature type cristobalite. Therefore, the phase transition at 220 to 260° C. does not occur and thus it is considered that the thermal expansion coefficient is low in the resin composition. An identification and quantification of the crystal phase are performed by a powder X-ray diffraction/Rietveld method. An assignment of the crystal can be performed by using, e.g., an X-ray database. Specifically, the analysis can be performed by a method described later.

It is preferable that the oxide powder contains 30% by mass or less of a crystal phase of low-temperature type cristobalite having Si or Si and at least either one of Ca and Al, based on the mass of the whole oxide powder (i.e., the mass of the whole oxide powder is 100% by mass). The content ratio of the crystal phase in the low-temperature type cristobalite being 30% by mass or less can achieve a lower thermal expansion coefficient in the resin composition. The content ratio of the crystal phase in the low-temperature type cristobalite is preferably 25% by mass or less, more preferably 20% by mass or less, and even more preferably 15% by mass or less. A lower limit of a range of the content ratio of the crystal phase in the low-temperature type cristobalite is not limited, and may be, e.g., 1% by mass or more. Also, the content ratio may be 0% by mass. The identification and the quantification of the crystal phase, and the assignment of the crystal can by performed in the same methods as those for the crystal of the high-temperature type cristobalite described above. Specifically, the analysis can be performed by a method described later.

It is preferable that the oxide powder contains 60% by mass or more of the crystal phases based on the mass of the whole oxide powder (i.e., the mass of the whole oxide powder is 100% by mass). The content ratio of the crystal phases of 60% by mass or more can achieve higher thermal conductivity in the resin composition. The content ratio of the crystal phases is preferably 65% by mass or more, more preferably 70% by mass or more, and even more preferably 80% by mass or more. An upper limit of a range of the content ratio of the crystal phases is not limited, and may be, e.g., 99% by mass or less. Also, the content ratio may be 100% by mass. The content ratio of the crystal phases can be measured by the same method as that for the crystal phase in the high-temperature type cristobalite described above. Specifically, the measurement can be performed by a method described later.

The oxide powder may contain other crystal phases and amorphous phases in addition to the crystal phase in the high-temperature type cristobalite and the crystal phase in the low-temperature type cristobalite. Examples of the other crystal phases include low-temperature type quartz, CaAl₂Si₂O₈, and CaSiO₃. A content ratio of the other crystal phases can be, e.g., 0 to 15% by mass, and 5 to 10% by mass, based on the mass of the whole oxide powder (i.e., the mass of the whole oxide powder is 100% by mass). Further, a content ratio of the amorphous phases can be, e.g., 0 to 40% by mass, and 5 to 35% by mass, based on the mass of the whole oxide powder (i.e., the mass of the whole oxide powder is 100% by mass). In addition, the oxide powder may not contain other crystal phases and the amorphous phases.

Within the scope achieving the effect in the present embodiments, the oxide powder may contain other elements in addition to Ca, Al and Si. However, from a point of view of the reliability of the electronic materials, a content of halogen in the oxide powder is preferably 0.1% by mass or less, more preferably 0.05% by mass or less, and even more preferably 0.01% by mass (100 ppm by mass) or less, based on the mass of the whole oxide powder (i.e., the mass of the whole oxide powder is 100% by mass), and it is particularly preferable that the oxide powder does not contain halogen. Furthermore, a halogen content in the present specification indicates the sum of fluorine, chlorine and bromine. From points of view of the reduction in dielectric constant and dielectric tangent and the reliability of the electronic materials, the sum of contents of Li, Na and K in the oxide powder is preferably less than 500 ppm by mass, more preferably less than 250 ppm by mass, and even more preferably less than 100 ppm by mass, based on the mass of the whole oxide powder (i.e., the mass of the whole oxide powder is 100% by mass), and it is particularly preferable that the oxide powder does not contain Li, Na and K. From the points of view of the reduction in dielectric constant and dielectric tangent and the reliability of the electronic materials, it is preferable that a content of impurities of metal elements such as Fe in the oxide powder is also low as much as possible.

An average particle diameter of the oxide powder is preferably 0.1 to 20 μm. The average particle diameter of 0.1 μm or more achieves easy blending to the resin. Also, the average particle diameter of 20 μm or less can achieve easy crystallization for the oxide powder when producing the oxide powder, thereby increasing the content of the crystal phase in the high-temperature type cristobalite having Ca, Al and Si. The average particle diameter is more preferably 0.5 to 18 μm, even more preferably 1 to 15 μm, and particularly preferably 3 to 10 μm. In addition, the average particle diameter is measured by using a laser diffraction particle size distribution measuring apparatus. Specifically, the measurement can be performed by a method described later.

An average circularity of the oxide powder is preferably 0.60 or more, more preferably 0.70 or more, and even more preferably 0.80 or more. The average circularity of 0.60 or more achieves a decrease in melt viscosity of the resin and improvement of flowability, thereby becoming easy for the oxide powder to blend to the resin. An upper limit of a range of the average circularity is not limited, and it is preferable that the average circularity has a higher value, and it may be 1. As described later, use of spherical raw material SiO₂ when producing the oxide powder can achieve a higher average circularity of the oxide powder. The average circularity is measured by the following method. A projected area (S) and a projected perimeter length (L) of the oxide particle photographed by using an electron microscope are obtained, to calculate the circularity by applying them to the following formula (1). Then, the average value of the circularity of all the oxide particles included in a given projected area circle (an area including the oxide particles of 100 or more) is calculated, and the average value is set to the average circularity. The average circularity can be measured by a method specifically described later.

Circularity=4πS/L² (1)

The oxide powder according to the present embodiments provides a resin composition which enables to exhibit the low thermal expansion coefficient, the high thermal conductivity and the low dielectric tangent when mixed with the resin, and therefore is useful as a filler filled in the resin composition which requires for these physical properties.

[Method for Producing Oxide Powder]

A method for producing the oxide powder according to the present embodiments includes the following steps: a step of mixing a Ca compound having a specific surface area of 2 m²/g or more, an Al compound having a specific surface area of 2 m²/g or more and SiO₂ to obtain a mixture (hereinafter, also referred to as a mixture production step); and a step of heating the mixture at 1,000 to 1,300° C. (hereinafter, also referred to as a heating step). According to the method according to the present embodiments, the oxide powder according to the present embodiments can be easily and effectively produced.

(Mixture Production Step)

In the present step, the Ca compound having a specific surface area of 2 m²/g or more, the Al compound having a specific surface area of 2 m²/g or more and SiO₂ are mixed to obtain the mixture. The Ca compound used as the raw material is not limited, and it is preferably CaO or compound generating CaO at a high temperature, and includes, e.g., CaO, CaCO₃, Ca(OH)₂, Ca(CH₃COO)₂, etc. One of these Ca compounds may be used alone, or two or more may be used in combination. Further, from a point of view of improvement of reactivity, it is preferable that the Ca compound of powder having a smaller particle diameter than the average particle diameter of the raw material SiO₂ is used. A powder which dissolves in a solvent such as water or alcohol, for example, Ca(CH₃COO)₂, etc., may be used to add into the solvent such as water or alcohol in a dissolved form, but it is preferable that it is added in a powder form from points of view of mass productivity and costs.

The specific surface area of the Ca compound is preferably 2 m²/g or more, more preferably 5 to 100 m²/g, and even more preferably 10 to 50 m²/g, from the point of view of the reactivity with SiO₂. In addition, the specific surface area is measured by a gas absorption method.

The Al compound used as the raw material is not limited, and it is preferably Al₂O₃ or a compound generating Al₂O₃ at a high temperature, and includes, e.g., Al₂O₃, Al(OH)₃, AlO(OH), Al(CH₃COO)₃, etc. One of these Al compounds may be used alone, or two or more may be used in combination. Further, from the point of view of the improvement of the reactivity, it is preferable that the Al compound of powder having a smaller particle diameter than the average particle diameter of the raw material SiO₂ is used. A powder which dissolves in a solvent such as water or alcohol, for example, Al(CH₃COO)₃, acetoalkoxyaluminum diisopropylate, etc., may be used to add into the solvent such as water or alcohol in a dissolved form, but it is preferable that it is added in a powder form from points of view of mass productivity and costs.

The specific surface area of the Al compound is preferably 2 m²/g or more, more preferably 10 to 500 m²/g, and even more preferably 50 to 300 m²/g, from the point of view of the reactivity with SiO₂. In addition, the specific surface area is measured by a gas absorption method.

With respect to SiO₂ used as the raw material, a crystalline system of amorphous, quartz, cristobalite, etc. is not limited, and a method for producing of SiO₂ is also not limited, and it is preferable that SiO₂ having 90% by mass or more of an amorphous phase is used, and more preferable that SiO₂ consisting of the amorphous phase is used. SiO₂ having 90% by mass or more of the amorphous phase includes SiO₂ produced by a flame fusion method, a deflagration method, a vapor phase method, a wet method, etc. Further, as described above, from the points of view of the reduction in dielectric constant and dielectric tangent and the reliability of the electronic materials, it is preferable that a total content of Li, Na and K in the raw material SiO₂ is small, e.g., less than 100 ppm by mass.

Since the particle diameter of the oxide powder obtained after heating principally reflects the particle diameter of the raw material SiO₂, the average particle diameter of the raw material SiO₂ is preferably 0.1 to 20 μm, more preferably 0.5 to 18 μm, even more preferably 1 to 15 μm, and particularly preferably 3 to 10 μm. Further, the average particle diameter is measured in the same manner as in the average particle diameter of the oxide powder. Also, since a shape of the oxide powder obtained after heating principally reflects the shape of the raw material SiO₂, it is preferable, because an average circularity of the oxide powder can be high, that spherical raw material SiO₂ is used. The average circularity of the raw material SiO₂ is preferably 0.60 or more, more preferably 0.70 or more, and even more preferably 0.80 or more. Further, the average circularity is measured in the same manner as in the average circularity of the oxide powder.

A mixing method of the Ca compound, the Al compound and SiO₂ may be either of dry mixing and wet mixing, but the dry mixing is preferable since it does not need to dry a solvent out because of not using the solvent, allowing a production cost of the oxide powder to be reduced. In addition, in case of mixing by the wet mixing, for example, after dissolving the Ca compound and the Al compound in the solvent such as water and alcohol, they can be mixed with SiO₂ and dried. Examples of the mixing method include a pulverizing machine such as an agate mortar, a ball mill, and a vibrating mill, and various mixers. A mixing ratio of the Ca compound, the Al compound and SiO₂ can be appropriately selected so that the contents of Ca, Al and Si in the oxide powder obtained are within a range of the present embodiments.

(Heating Step)

In the present step, the mixture obtained in the mixture production step is heated at 1,000 to 1,300° C. A heating apparatus which heats the mixture is not limited if it is the apparatus that can heat at a high temperature, and includes, e.g., an electric furnace, a rotary kiln, a pusher furnace, etc. A heating atmosphere is not limited, and includes, e.g., under an air, N₂, Ar, vacuum, etc.

A heating temperature is preferably 1,000 to 1,300° C., more preferably 1,050 to 1,250° C., and even more preferably 1,100 to 1,200° C. The heating temperature of 1,000° C. or more achieves to shorten a time required for crystallization and also to be able to fully perform the crystallization, thereby increasing the content ratio of the crystal phase in the high-temperature type cristobalite. Further, the heating temperature of 1,300° C. or less achieves to be able to suppress fusion between particles and to reduce formation of aggregates, thereby being easy to mix the oxide powder obtained with the resin. The heating time is depending on the heating temperature, and preferably 1 to 24 hours, more preferably 2 to 15 hours, and even more preferably 3 to 10 hours. The heating time of 1 hour or more achieves to be able to fully perform the crystallization to the high-temperature type cristobalite. Further, the heating time of 24 hours or less achieves to be able to improve production capacity.

The oxide powder obtained after heating sometimes becomes aggregates which a plurality of particles agglutinate. The aggregates themselves may be utilized as the oxide powder, or after crushing the aggregates as needed, these may be used as the oxide powder. A crushing method of the aggregates is not limited, and includes methods for crushing by, e.g., an agate mortar, a ball mill, a vibrating mill, a jet mill, a wet jet mill, etc. The crushing may be performed in a dry process, or may be performed in a wet process by mixing with a liquid such as water or alcohol. In the crushing by the wet process, the oxide powder is obtained by drying after the crushing. The drying method is not limited, and includes, e.g., heat drying, vacuum drying, freeze drying, supercritical carbon dioxide drying, etc.

(Other Steps)

The method for producing the oxide powder according to the present embodiments may further include other steps such as a classification step to classify the oxide powder so as to obtain a desired average particle diameter, a surface treatment step using a coupling agent, and a washing step to reduce impurities, in addition to the mixture production step and the heating step. By performing the surface treatment step, a blending amount (filling amount) of the oxide powder to the resin can be further increased. As the coupling agent used for the surface treatment, a silane coupling agent is preferable, and e.g., a titanate coupling agent, an aluminate coupling agent, etc. can be used.

[Resin Composition]

The resin composition according to the present embodiments contains the oxide powder according to the present embodiments and the resin. The resin composition according to the present embodiments can exhibit the low thermal expansion coefficient, the high thermal conductivity and the low dielectric tangent because of containing the oxide powder according to the present embodiments. Further, the resin composition according to the present embodiments has high flowability due to low viscosity, and thus is excellent in moldability.

The resin is not limited, and examples thereof include polyethylene, polypropylene, an epoxy resin, a silicone resin, a phenol resin, a melamine resin, a urea resin, an unsaturated polyester, a fluorine resin, polyimide, polyamide imide, a polyamide such as polyetherimide, polybutylene terephthalate, a polyester such as polyethylene terephthalate, polyphenylene sulfide, a wholly aromatic polyester, a polysulfone, a liquid crystal polymer, polyethersulfone, polycarbonate, a maleimide modified resin, an ABS resin, an AAS (acrylonitrile-acryl rubber-styrene) resin, and an AES (acrylonitrile-ethylene-propylene-diene rubber-styrene) resin. One of these resins may be used alone, or two or more may be used in combination.

A content of the oxide powder in the resin composition is appropriately selected depending on the intended physical properties such as the thermal expansion coefficient, the thermal conductivity, the dielectric constant and the dielectric tangent, and is preferably 2 to 89% by mass, more preferably 10 to 79% by mass, and even more preferably 20 to 72% by mass. A content of the resin in the resin composition is preferably 11 to 98% by mass, more preferably 21 to 90% by mass, and even more preferably 28 to 80% by mass.

The resin composition according to the present embodiments can contain other components in addition to the oxide powder according to the present embodiments and the resin. Examples of the other components include a coupling agent, a flame retardant, and glass cloth. Further, by further mixing other powder of which the composition, the specific surface area and the average particle diameter are different, in addition to the oxide powder according to the present embodiments, the dielectric constant, the dielectric tangent, the thermal expansion coefficient, the thermal conductivity, the filling ratio, etc. of the resin composition can be easily adjusted.

The thermal expansion coefficient of the resin composition according to the present embodiments is preferably 40×10⁻⁶/° C. or less, and more preferably 35×10⁻⁶/° C. or less. The thermal conductivity of the resin composition according to the present embodiments is preferably 0.75 W/m·K or more, and more preferably 0.80 W/m·K or more. The dielectric tangent of the resin composition according to the present embodiments is preferably 4.0×10⁻⁴ or less, and more preferably 3.5×10⁻⁴ or less. Further, the thermal expansion coefficient, the thermal conductivity and the dielectric tangent of the resin composition are values measured by methods described later.

The resin composition according to the present embodiments is particularly useful as a resin composition for high-frequency substrates because it exhibits the low thermal expansion coefficient, the high thermal conductivity and the low dielectric tangent. Specific examples of the high-frequency substrates include a fluorine substrate, a PPE substrate, and a ceramic substrate.

### EXAMPLES

Hereinafter, the embodiments of the present invention will be specifically described with reference to examples, but the present invention is not limited to these examples.

### Example 1

CaCO₃ (Trade Name: CWS-20, manufactured by Sakai Chemical Industry Co., Ltd., Specific Surface Area: 20 m²/g), Al₂O₃(Trade Name: AEROXIDE AluC, manufactured by Nippon Aerosil Co., Ltd., Specific Surface Area: 100 m²/g), and spherical amorphous SiO₂(Trade Name: AF-6C, manufactured by Suzuki Yushi Industrial Co., Ltd., Average Particle Diameter: 4 μm, Average Circularity: 0.95) were used as the raw materials with the amounts added as shown in Table 1, respectively. Ethanol and alumina beads (5 mm ϕ) were added to these raw materials and mixed using a vibrating mixer (manufactured by Resodyn Acoustic Mixers, Inc., Trade Name: Low-Frequency Resonant Acoustic Mixer, Lab RAM II). The alumina beads were taken out of the mixture obtained and the ethanol was dried out. 10 g of this mixture was put in an alumina crucible and heated in an electric furnace by increasing a temperature from room temperature at 10° C./min. At this time, a heating temperature was 1,200° C. and a heating time was 4 hours. After heating, samples were spontaneously cooled, and crushed in an agate mortar after the samples were cooled, to obtain oxide powder. The oxide powder was evaluated by methods described later.

### Examples 2, 3 and 7 to 9, and Comparative Examples 1 to 5

Each oxide powder was prepared and evaluated in the same manner as in Example 1 except that the amounts of the raw materials added, the heating time and the heating temperature were changed to the conditions shown in Table 1 or Table 2.

### Example 4

Oxide powder was prepared and evaluated in the same manner as in Example 1 except that the spherical amorphous SiO₂(Trade Name: E-90C, manufactured by Suzuki Yushi Industrial Co., Ltd., Average Particle Diameter: 19 μm, Average Circularity: 0.95) was used as the raw material SiO₂, and the heating time was changed to the condition shown in Table 1.

### Example 5

Oxide powder was prepared and evaluated in the same manner as in Example 1 except that the spherical amorphous SiO₂ (Trade Name: SFP-30M, manufactured by Denka Company Ltd., Average Particle Diameter: 0.6 μm, Average Circularity: 0.95) was used as the raw material SiO₂.

### Example 6

Oxide powder was prepared and evaluated in the same manner as in Example 1 except that the spherical amorphous SiO₂ (Trade Name: Sciqas, manufactured by Sakai Chemical Industry Co., Ltd., Average Particle Diameter: 0.1 μm, Average Circularity: 1.00) was used as the raw material SiO₂, and the heating temperature was changed to the condition shown in Table 1.

### Example 10

Oxide powder was prepared and evaluated in the same manner as in Example 1 except that the spherical amorphous SiO₂ (Trade Name: B-6C, manufactured by Suzuki Yushi Industrial Co., Ltd., Average Particle Diameter: 4 μm, Average Circularity: 0.95) was used as the raw material SiO₂, and the heating temperature was changed to the condition shown in Table 1.

### Comparative Example 6

Oxide powder was prepared and evaluated in the same manner as in Example 1 except that the spherical amorphous SiO₂ (Trade Name: FB-40R, manufactured by Denka Company Ltd., Average Particle Diameter: 40 μm, Average Circularity: 0.95) was used as the raw material SiO₂.

### Comparative Example 7

Spherical amorphous SiO₂ (manufactured by Suzuki Yushi Industrial Co., Ltd., Average Particle Diameter: 4 μm, Average Circularity: 0.95) was evaluated in the same manner as in Example 1.

### Comparative Example 8

Spherical amorphous SiO₂ (Trade Name: FB-5D, manufactured by Denka Company Ltd., Average Particle Diameter: 5 μm) and Al₂O₃ (Trade Name: AEROXIDE AluC, manufactured by Nippon Aerosil Co., Ltd., Specific Surface Area: 100 m²/g) were fully mixed with a ratio of 98.5 parts by mass of SiO₂ and 1.5 parts by mass of Al₂O₃ by using a mixer (manufactured by Nippon Eirich Co., Ltd., Trade Name: EL-1). The mixture obtained was heated at 1,300° C. for 2 hours, to prepare oxide powder, and evaluated in the same manner as in Example 1.

Each property of the oxide powder prepared in each Example and Comparative Example was evaluated by the following method. Each evaluation result is shown in Table 1 and Table 2.

[Identification of Crystal Phases and Measurement of Content of Crystal Phases]

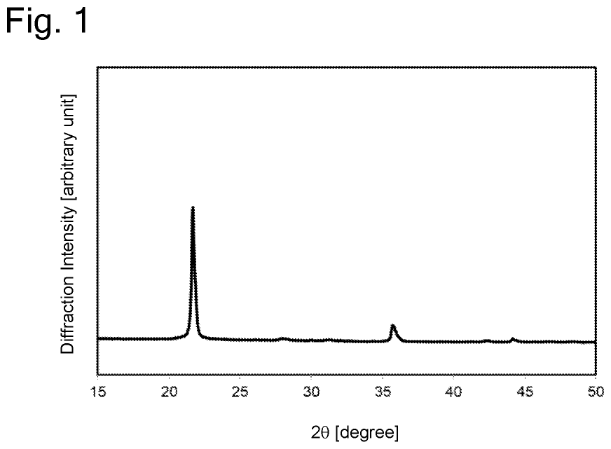

Identification of the crystal phases included in the oxide powder and measurement of contents of the crystal phases were performed by the powder X-ray diffraction measurement/Rietveld method. As a measurement apparatus, a sample horizontal-type multipurpose X-ray diffractometer (manufactured by Rigaku Corporation, Trade Name: RINT-Ultima IV) was used. The measurement was performed under the following conditions: an X-ray source: CuKα, tube voltage: 40 kV, tube current: 40 mA, scan speed: 10.0°/min, and 2θ scan range: 10° to 80°. An X-ray diffraction pattern of the powder of Example 1 is shown in FIG. 1. For quantitative analysis of the crystal phases, Rietveld method software (manufactured by MDI, Trade Name: Integrated Powder X-ray Software Jade+9.6) was used. Ratios (% by mass) of various crystal phases were calculated by the Rietveld analysis after performing the X-ray diffraction measurement on a sample to which the oxide powder was added so that the content of α-alumina (an internal standard substance) which was a standard sample for the X-ray diffraction manufactured by NIST was 50% by mass (based on the total amount of the sample after addition).

[Measurement of Converted Contents of Ca, Al and Si, and Impurity (Li, Na and K) Contents]

The measurement of converted contents of Ca, Al and Si as CaO, Al₂O₃ and SiO₂, and impurity (Li, Na and K) contents were performed by inductively coupled plasma emission spectrometric analysis. As an analysis apparatus, an ICP emission spectrophotometer (manufactured by SPECTRO Analytical Instruments GmbH, Trade Name: CIROS-120) was used. In the measurement of the converted contents of Ca, Al and Si, 0.01 g of the oxide powder was weighed in a platinum crucible, melted with flux in which potassium carbonate, sodium carbonate and boric acid were mixed and then dissolved by adding further hydrochloric acid to prepare a measurement solution. Further, in the measurement of the impurities, 0.1 g of the oxide powder was weighed in a platinum crucible, and the measurement solution was prepared by performing pressurized acidolysis at 200° C. using hydrofluoric acid and sulfuric acid. With respect to the impurity (Li, Na and K) contents, in Table 1 and Table 2, the total contents of Li, Na and K are shown.

[Measurement of Impurity (Halogen) Contents]

The measurement of the impurity (halogen) contents was performed by combustion ion chromatography. As an analysis apparatus, combustion-ion chromatograph analysis apparatus (Combustion Part: manufactured by Mitsubishi Chemical Analytech Co., Ltd., Trade Name: AQF-2100H/Measurement Part: manufactured by Thermo Fisher Scientific Inc., Trade Name: ICS-1500) was used. In the measurement of the halogen (fluorine, chlorine, bromine) contents, 0.1 g of the sample was weighed in an alumina boat and set up in a combustion decomposition unit, and burned in a combustion gas flow containing oxygen, to collect gases generated to an absorbing solution. The various halogen ions collected in the absorbing solution were separated and quantified by the ion chromatography.

[Average Circularity]

After fixing the oxide powder on a sampling stage with a carbon tape, osmium coating was performed, and an image with a magnification of 500 to 5,000 times and a resolution of 2,048×1,356 pixels, photographed by a scanning electron microscopy (manufactured by JEOL Ltd., Trade Name: JSM-7001FSHL) was captured in a personal computer. From this image, using an image analysis apparatus (manufactured by Nippon Roper, K.K., Trade Name: Image-Pro Premier Ver. 9.3), the projected area (S) of the oxide particle and the projected perimeter length (L) of the oxide particle were calculated, to calculate the circularity by the following formula (1). The circularity of 100 oxide particles having 0.1 μm or more of an arbitrary projected area circle-equivalent diameter obtained in this way were found and an average of them was set to the average circularity.

Circularity=4πS/L² (1)

[Average Particle Diameter]

By using a laser diffraction particle size distribution measuring apparatus (manufactured by Beckman Coulter Inc., Trade Name: LS 13 320), the measurement of the average particle diameter was performed. 50 cm³ of pure water and 0.1 g of the oxide powder were put in a glass beaker, and distribution process was performed for 1 minute by using an ultrasonic homogenizer (manufactured by Branson Ultrasonics Corporation, Trade Name: SFX250). A dispersion liquid of the oxide powder which was subjected to the distribution process was added to the laser diffraction particle size distribution measuring apparatus drop by drop using a dropper, and 30 seconds after adding a predetermined quantity, the measurement was performed. From data of optical intensity distribution of diffracted/scattered light due to the oxide particles which was detected by a sensor in the laser diffraction particle size distribution measuring apparatus, the particle size distribution was calculated. The average particle diameter was obtained by multiplying a value of the particle diameter measured and a relative particle amount (difference %), and further divided by the sum of the relative particle amounts (100%). Here, % means % by volume.

[Thermal Expansion Coefficient of Resin Composition]

25.6 parts by mass of bisphenol F liquid epoxy resin (manufactured by Mitsubishi Chemical Corporation, Trade Name: JER807) and 6.4 parts by mass of 4,4′-diaminophenylmethane (manufactured by Tokyo Chemical Industry Co., Ltd.) were mixed while melting at 95° C. The oxide powder was added to this mixture to be 63% by mass, and mixed using a planetary mixer (manufactured by Thinky Corporation, Trade Name: Awatori Neritarou AR-250, Rotation Frequency of 2,000 rpm). The mixture obtained was poured into a mold (3 cm square×5 mm thickness) made of silicone which was heated in advance and left it stand at 80° C. for 20 minutes. After that, using a vacuum heating press (manufactured by Imoto Machinery Co., Ltd., Trade Name: IMC-1674-A), it was subjected to press heat curing in the order of 80° C./1 hour/1.5 MPa, 150° C./1 hour/2.5 MPa and 200° C./0.5 hours/5 MPa. The sample after curing was processed into a sample size (4×4×15 mm) for the measurement and the thermal expansion coefficient was measured by TMA (manufactured by Bruker Corporation, Trade Name: TMA4000SA). The measurement was performed under the conditions of a temperature increasing rate of 5° C./min, a measurement temperature range of −10° C. to 280° C. and a nitrogen atmosphere, to calculate the thermal expansion coefficient at 0° C. to 100° C. from a TMA measurement chart obtained.

[Thermal Conductivity of Resin Composition]

The thermal conductivity of the resin composition was calculated by multiplying all of thermal diffusivity, specific gravity and specific heat. Blending and curing of the resin composition were performed in the same conditions as in the evaluation of the thermal expansion coefficient. The sample was processed into one having a width of 10 mm×10 mm×a thickness of 1 mm, to obtain the thermal diffusivity by a laser flash method. As the measurement apparatus, a xenon flash analyzer (manufactured by NETZSCH geratebau GmbH, Trade Name: LFA447 NanoFlash) was used. The specific gravity was obtained by the Archimedes method. Using a differential scanning calorimeter (manufactured by TA Instruments, Trade Name: Q2000), the specific heat was obtained by raising a temperature from room temperature to 200° C. at a temperature increasing rate of 10° C./min under a nitrogen atmosphere.

[Dielectric Constant and Dielectric Tangent of Resin Composition]

The oxide powder and polyethylene powder (manufactured by Sumitomo Seika Chemicals Company Ltd., Trade Name: FLO-THENE UF-20S) were weighed to be 52% by mass of the filling amount of the oxide powder and mixed using a vibrating mixer manufactured by Resodyn Acoustic Mixers, Inc. (Acceleration of 60 g, Treatment Time of 2 minutes). The mixed powder obtained was measured at a predetermined volume (to be about 0.5 mm in thickness), and put in a metal mold having a diameter of 3 cm, to make a sheet under the conditions of 140° C., 5 minutes and 30,000 N in a nanoimprint apparatus (manufactured by SCIVAX Corporation, Trade Name: X-300), to provide an evaluation sample. A thickness of the sheet of the evaluation sample is about 0.5 mm. A shape and a size of the sample do not affect the evaluation results if it could be mounted to a measuring apparatus, and it is about 1 to 3 cm square.

Measurement of dielectric properties was performed by the following method. A 36 GHz cavity resonator (manufactured by SUMTECH, Inc.) was connected with a vector network analyzer (Trade Name: 85107, manufactured by Keysight Technologies) and the evaluation sample (1.5 cm square, 0.5 mm thickness) was set to close a hole having a diameter of 10 mm provided in the resonator, to measure a resonance frequency (f0) and no-load Q value (Qu). The evaluation sample was rotated for each measurement, the measurement was repeated 5 times in the same manner, and the averages of f0 and Qu obtained were taken as the measured values. Using analysis software (software manufactured by SUMTECH, Inc.), the dielectric constant and the dielectric tangent (tan δc) were calculated from f0 and Qu, respectively. The measurement temperature was 20° C. and humidity was 60% RH.

[Comprehensive Evaluation]

The resin composition was evaluated as “A” in case of meeting all of 40×10⁻⁶/° C. or less of the thermal expansion coefficient, 0.75 W/m·K or more of the thermal conductivity and 4.0×10⁻⁴ or less of the dielectric tangent, “B” in case of meeting two of them and “C” in case of meeting one of them or not meeting all of them.

TABLE 1

| | | Unit | Example 1 | Example 2 | Example 3 | Example 4 | Example 5 | Example 6 |
|---|---|---|---|---|---|---|---|---|
| Particle Diameter of Raw Material SiO₂ | | μm | 4 | 4 | 4 | 16 | 0.6 | 0.1 |
| Amount of Raw | CaO | % by mole | 3.5 | 1.5 | 5 | 3.5 | 3.5 | 3.5 |
| Material Added | Al₂O₃ | % by mole | 3.5 | 1.5 | 5 | 3.5 | 3.5 | 3.5 |
| | SiO₂ | % by mole | 93 | 97 | 90 | 93 | 93 | 93 |
| Contents of Ca, Al and | CaO | % by mole | 3.5 | 1.5 | 5 | 3.5 | 3.5 | 3.5 |
| Si in Oxide Powder | Al₂O₃ | % by mole | 3.5 | 1.5 | 5 | 3.5 | 3.5 | 3.5 |
| (Converted Contents) | SiO₂ | % by mole | 93 | 97 | 90 | 93 | 93 | 93 |

| | | | | | | | |
|---|---|---|---|---|---|---|---|
| Heating Temperature | ° C. | 1200 | 1200 | 1200 | 1200 | 1200 | 1100 |
| Heating Time | hours | 4 | 8 | 4 | 8 | 4 | 4 |
| Content Ratio of Crystal Phases (A + B + C) | % by mass | 90 | 85 | 87 | 68 | 95 | 100 |
| Content Ratio of High-Temperature Type | % by mass | 67 | 60 | 63 | 52 | 67 | 67 |
| Cristobalite (A) | | | | | | | |
| Content Ratio of Low-Temperature Type | % by mass | 14 | 11 | 15 | 7 | 18 | 20 |
| Cristobalite (B) | | | | | | | |
| Content Ratio of Other Crystal Phases (C) | % by mass | 9 | 14 | 9 | 9 | 10 | 13 |
| Content Ratio of Amorphous Phase | % by mass | 10 | 15 | 13 | 32 | 5 | 0 |
| Halogen Content | ppm | less | less | less | less | 20 | less |
| | | than 10 | than 10 | than 10 | than 10 | | than 10 |
| Total Content of Li, Na and K | ppm | 290 | 330 | 240 | 300 | 60 | less |
| | | | | | | | than 10 |
| Average Particle Diameter | μm | 5 | 7 | 6 | 18 | 0.8 | 0.5 |
| Average Circularity | — | 0.90 | 0.75 | 0.80 | 0.80 | 0.75 | 0.70 |
| Thermal Expansion Coefficient of Resin | 10⁻⁶/° C. | 34 | 35 | 35 | 34 | 34 | 36 |
| Composition | | | | | | | |
| Thermal Conductivity of Resin Composition | W/mK | 0.91 | 0.82 | 0.83 | 0.78 | 0.94 | 0.91 |
| Dielectric Constant of Resin Composition | — | 2.6 | 2.6 | 2.6 | 2.6 | 2.6 | 2.6 |
| Dielectric Tangent of Resin Composition | 10⁻⁴ | 3.4 | 3.8 | 3.8 | 3.8 | 3.4 | 3.5 |
| Comprehensive Evaluation | | A | A | A | A | A | A |

| | | Unit | Example 7 | Example 8 | Example 9 | Example 10 |
|---|---|---|---|---|---|---|
| Particle Diameter of Raw Material SiO₂ | | μm | 4 | 4 | 4 | 4 |
| Amount of Raw | CaO | % by mole | 3.5 | 3.5 | 3.5 | 3.5 |
| Material Added | Al₂O₃ | % by mole | 3.5 | 3.5 | 3.5 | 3.5 |
| | SiO₂ | % by mole | 93 | 93 | 93 | 93 |
| Contents of Ca, Al and | CaO | % by mole | 3.5 | 3.5 | 3.5 | 3.5 |
| Si in Oxide Powder | Al₂O₃ | % by mole | 3.5 | 3.5 | 3.5 | 3.5 |
| (Converted Contents) | SiO₂ | % by mole | 93 | 93 | 93 | 93 |

| | | | | | |
|---|---|---|---|---|---|
| Heating Temperature | ° C. | 1100 | 1300 | 1100 | 1200 |
| Heating Time | hours | 24 | 2 | 4 | 4 |
| Content Ratio of Crystal Phases (A + B + C) | % by mass | 64 | 100 | 61 | 90 |
| Content Ratio of High-Temperature Type | % by mass | 57 | 70 | 45 | 62 |
| Cristobalite (A) | | | | | |
| Content Ratio of Low-Temperature Type | % by mass | 5 | 17 | 6 | 18 |
| Cristobalite (B) | | | | | |
| Content Ratio of Other Crystal Phases (C) | % by mass | 2 | 13 | 10 | 10 |
| Content Ratio of Amorphous Phase | % by mass | 36 | 0 | 39 | 10 |
| Halogen Content | ppm | less | less | less | less |
| | | than 10 | than 10 | than 10 | than 10 |
| Total Content of Li, Na and K | ppm | 280 | 400 | 320 | 270 |
| Average Particle Diameter | μm | 6 | 5 | 3 | 5 |
| Average Circularity | — | 0.85 | 0.85 | 0.90 | 0.85 |
| Thermal Expansion Coefficient of Resin | 10⁻⁶/° C. | 38 | 34 | 35 | 34 |
| Composition | | | | | |
| Thermal Conductivity of Resin Composition | W/mK | 0.77 | 0.89 | 0.79 | 0.87 |
| Dielectric Constant of Resin Composition | — | 2.6 | 2.6 | 2.6 | 2.4 |
| Dielectric Tangent of Resin Composition | 10⁻⁴ | 4.0 | 3.1 | 3.7 | 3.9 |
| Comprehensive Evaluation | | A | A | A | A |

TABLE 2

| | | | Compar- | Compar- | Compar- | Compar- | Compar- | Compar- |
|---|---|---|---|---|---|---|---|---|
| | | | ative | ative | ative | ative | ative | ative |
| | | Unit | Example 1 | Example 2 | Example 3 | Example 4 | Example 5 | Example 6 |
| Particle Diameter of Raw Material SiO₂ | | μm | 4 | 4 | 4 | 4 | 4 | 40 |
| Amount of Raw | CaO | % by mole | 0.5 | 7.5 | 0.5 | 2.5 | 3.5 | 3.5 |
| Material Added | Al₂O₃ | % by mole | 0.5 | 7.5 | 5 | 5 | 3.5 | 3.5 |
| | SiO₂ | % by mole | 99 | 85 | 94.5 | 92.5 | 93 | 93 |
| Contents of Ca, Al and | CaO | % by mole | 0.5 | 7.5 | 0.5 | 2.5 | 3.5 | 3.5 |
| Si in Oxide Powder | Al₂O₃ | % by mole | 0.5 | 7.5 | 5 | 5 | 3.5 | 3.5 |
| (Converted Contents) | SiO₂ | % by mole | 99 | 85 | 94.5 | 92.5 | 93 | 93 |

| | | | | | | | |
|---|---|---|---|---|---|---|---|
| Heating Temperature | ° C. | 1200 | 1200 | 1300 | 1200 | 1200 | 1200 |
| Heating Time | hours | 4 | 4 | 2 | 4 | 0.5 | 4 |
| Content Ratio of Crystal Phases | % by mass | 55 | 87 | 85 | 77 | 38 | 52 |
| (A + B + C) | | | | | | | |
| Content Ratio of High-Temperature Type | % by mass | 37 | 35 | 0 | 11 | 20 | 35 |
| Cristobalite (A) | | | | | | | |
| Content Ratio of Low-Temperature Type | % by mass | 11 | 15 | 83 | 39 | 9 | 10 |
| Cristobalite (B) | | | | | | | |
| Content Ratio of Other Crystal Phases (C) | % by mass | 7 | 37 | 2 | 27 | 9 | 7 |
| Content Ratio of Amorphous Phase | % by mass | 45 | 13 | 15 | 23 | 62 | 48 |
| Halogen Content | ppm | less | less | less | less | less | less |
| | | than 10 | than 10 | than 10 | than 10 | than 10 | than 10 |
| Total Content of Li, Na and K | ppm | 320 | 410 | 290 | 300 | 290 | 70 |
| Average Particle Diameter | μm | 5 | 5 | 4 | 5 | 5 | 5 |
| Average Circularity | — | 0.80 | 0.80 | 0.90 | 0.85 | 0.80 | 0.80 |
| Thermal Expansion Coefficient of Resin | 10⁻⁶/° C. | 34 | 35 | 43 | 39 | 32 | 38 |
| Composition | | | | | | | |
| Thermal Conductivity of Resin Composition | W/mK | 0.49 | 0.78 | 0.85 | 0.79 | 0.42 | 0.51 |
| Dielectric Constant of Resin Composition | — | 2.6 | 2.6 | 2.6 | 2.6 | 2.6 | 2.6 |
| Dielectric Tangent of Resin Composition | 10⁻⁴ | 4.9 | 4.2 | 3.7 | 4.5 | 4.8 | 4.5 |
| Comprehensive Evaluation | | C | B | B | B | C | C |

| | | Comparative | Comparative |
|---|---|---|---|
| | Unit | Example 7 | Example 8 |
| Content Ratio of Crystal Phases | % by mass | 0 | 99 |
| (A + B + C) | | | |
| Content Ratio of High-Temperature Type | % by mass | 0 | 0 |
| Cristobalite (A) | | | |
| Content Ratio of Low-Temperature Type | % by mass | 0 | 99 |
| Cristobalite (B) | | | |
| Content Ratio of Other Crystal Phases (C) | % by mass | 0 | 0 |
| Content Ratio of Amorphous Phase | % by mass | 100 | 1 |
| Halogen Content | ppm | less than 10 | less than 10 |
| Total Content of Li, Na and K | ppm | 310 | 80 |
| Average Particle Diameter | μm | 5 | 7 |
| Thermal Expansion Coefficient of Resin | 10⁻⁶/° C. | 32 | 43 |
| Composition | | | |
| Thermal Conductivity of Resin Composition | W/mK | 0.34 | 0.92 |
| Dielectric Constant of Resin Composition | — | 2.6 | 2.6 |
| Dielectric Tangent of Resin Composition | 10⁻⁴ | 12 | 3.5 |
| Comprehensive Evaluation | | C | B |

As shown in Table 1 and Table 2, it was found that the resin compositions containing the oxide powder of Examples 1 to 10 which were embodiments of the present invention were low in thermal expansion coefficient and dielectric tangent, and high in thermal conductivity.

1. Oxide powder comprising Ca, Al and Si;
wherein the oxide powder comprises 40% by mass or more of a crystal phase of high-temperature type cristobalite comprising Ca, Al and Si, based on the mass of the whole oxide powder; and
wherein contents of Ca, Al and Si in the oxide powder are 1 to 5% by mole of CaO, 1 to 5% by mole of Al₂O₃ and 90 to 98% by mole of SiO₂, respectively (the sum of contents of CaO, Al₂O₃ and SiO₂ is 100% by mole) when converting the contents of Ca, Al and Si to contents of CaO, Al₂O₃ and SiO₂.

2. The oxide powder according to claim 1, wherein the oxide powder comprises 60% by mass or more of the crystal phase, based on the mass of the whole oxide powder.

3. The oxide powder according to claim 1, wherein the oxide powder comprises 30% by mass or less of a crystal phase of low-temperature type cristobalite comprising Si or Si and at least either one of Ca and Al, based on the mass of the whole oxide powder.

4. The oxide powder according to claim 1, wherein an average particle diameter of the oxide powder is 0.1 to 20 μm.

5. The oxide powder according to claim 1, wherein a content of halogen in the oxide powder is 0.1% by mass or less, based on the mass of the whole oxide powder.

6. The oxide powder according to claim 1, wherein the sum of contents of Li, Na and K in the oxide powder is less than 500 ppm by mass, based on the mass of the whole oxide powder.

7. A method for producing the oxide powder according to claim 1, comprising:
a step of mixing a Ca compound having a specific surface area of 2 m²/g or more, an Al compound having a specific surface area of 2 m²/g or more and SiO₂ to obtain a mixture; and
a step of heating the mixture at 1,000 to 1,300° C.

8. A resin composition comprising the oxide powder according to claim 1 and a resin.

9. The resin composition according to claim 8, wherein a content of the oxide powder in the resin composition is 2 to 89% by mass.

10. The resin composition according to claim 8, which is a resin composition for high frequency substrate.
